(19) United States
(12) Patent Application Publication
(10) Pub. No.: US 2022/0363071 A1
(43) Pub. Date: Nov. 17, 2022

(54) THERMAL HEAD DRIVING INTEGRATED CIRCUIT AND METHOD OF MANUFACTURING THERMAL HEAD DRIVING INTEGRATED CIRCUIT

(71) Applicant: ABLIC Inc., Tokyo (JP)

(72) Inventor: Yuji WAKABAYASHI, Tokyo (JP)

(21) Appl. No.: 17/732,860

(22) Filed: Apr. 29, 2022

(30) Foreign Application Priority Data
May 11, 2021 (JP) 2021-080108

(51) Int. Cl. B41J 2/355; B41J 2/335

(52) U.S. Cl. CPC B41J 2/355; B41J 2/3352; B41J 2/3359

(57) ABSTRACT

Provided are a thermal head driving integrated circuit and a method of manufacturing the thermal head driving integrated circuit. The thermal head driving integrated circuit includes: an input terminal and an output terminal for a data signal transfer clock signal; an IC internal wiring line arranged between the input terminal and the output terminal; and a duty ratio correction circuit connected to the output terminal. The duty ratio correction circuit includes: a first first-conductivity-type MOS transistor; a second first-conductivity-type MOS transistor; a first second-conductivity-type MOS transistor; a second second-conductivity-type MOS transistor; a first resistor circuit including a first resistor and a first fuse connected in parallel to each other; and a second resistor circuit including a second resistor and a second fuse connected in parallel to each other. The method includes cutting a fuse of the resistor circuit.

### RELATED APPLICATIONS

This application claims priority to Japanese Patent Application No. 2021-080108, filed on May 11, 2021, the entire content of which is incorporated herein by reference.

### BACKGROUND OF THE INVENTION

### 1. Field of the Invention

The present invention relates to a thermal head driving integrated circuit and a method of manufacturing thermal head driving integrated circuit.

### 2. Description of the Related Art

There are a large number of examples in which a thermal head driving integrated circuit (“integrated circuit” is hereinafter abbreviated as “IC” in some cases) is used so that a plurality of driving ICs are connected in a cascade connection. Some thermal head driving ICs include an IC internal wiring line crossing the inside of the IC in order to improve efficiency of a substrate area in which the thermal head driving IC is mounted (see, for example, Japanese Patent Application Laid-open No. Hei 05-298036).

### SUMMARY OF THE INVENTION

The present invention has an object to provide a thermal head driving IC with which a duty ratio of a signal passing through an IC internal wiring line of the thermal head driving IC is maintained while the signal is prevented from being distorted.

According to at least one embodiment of the present invention, there is provided a thermal head driving integrated circuit, including: an input terminal and an output terminal for a data signal transfer clock signal; an IC internal wiring line arranged between the input terminal and the output terminal; and a duty ratio correction circuit connected to the output terminal for the data signal transfer clock signal, wherein the duty ratio correction circuit includes a first node, a second node, a first first-conductivity-type MOS transistor, a second first-conductivity-type MOS transistor, a first second-conductivity-type MOS transistor, a second second-conductivity-type MOS transistor, a first resistor circuit, a second resistor circuit, a first power supply terminal, and a second power supply terminal, the first resistor circuit including a first resistor and a first fuse connected in parallel to each other between a third node and a fourth node, the second resistor circuit including a second resistor and a second fuse connected in parallel to each other between a fifth node and a sixth node, wherein the first first-conductivity-type MOS transistor includes a source terminal connected to the first power supply terminal, a gate terminal connected to the third node, and a drain terminal connected to a source terminal of the second first-conductivity-type MOS transistor, wherein the second first-conductivity-type MOS transistor includes a gate terminal connected to the first node and the fourth node, and a drain terminal connected to the second node, wherein the first second-conductivity-type MOS transistor includes a gate terminal connected to the first node and the fifth node, a drain terminal connected to the second node, and a source terminal connected to a drain terminal of the second second-conductivity-type MOS transistor, and wherein the second second-conductivity-type MOS transistor includes a gate terminal connected to the sixth node, and a source terminal connected to the second power supply terminal. Further, according to at least one embodiment of the present invention, there is provided a method of manufacturing the thermal head driving integrated circuit, the method including cutting a fuse of one of the first resistor circuit or the second resistor circuit.

### BRIEF DESCRIPTION OF THE DRAWINGS

FIG. 1 is a block diagram for illustrating an example of a thermal head driving IC according to a first embodiment of the present invention.

FIG. 2 is a circuit diagram for illustrating an example of a duty ratio correction circuit in the first embodiment of the present invention.

FIG. 3 is a circuit diagram for illustrating an example of a resistor circuit in the first embodiment of the present invention.

FIG. 4 is a diagram for illustrating various waveforms of a data signal transfer clock signal.

FIG. 5 is a diagram for illustrating an example of duty ratio correction of a data signal transfer clock signal waveform in the first embodiment of the present invention.

FIG. 6 is a diagram for illustrating another example of the duty ratio correction of the data signal transfer clock signal waveform in the first embodiment of the present invention.

### DETAILED DESCRIPTION OF THE PREFERRED EMBODIMENTS

### First Embodiment

Now, description is given of a first embodiment of the present invention with reference to the drawings. FIG. 1 is a circuit diagram for illustrating an example of a thermal head driving IC 1 according to the first embodiment.

The thermal head driving IC 1 according to the first embodiment includes an input terminal 6 and an output terminal 7 for a data signal transfer clock signal, an input terminal 8 and an output terminal 9 for a data signal, a shift register circuit 3, a duty ratio correction circuit 2, buffer amplifiers 11, 13, and 14, an inverter 12, latch circuits 4, and a thermal head drive circuit 5. The shift register circuit 3 is connected between the input terminal 8 and the output terminal 9 for the data signal, and receives the data signal and the data signal transfer clock signal. The duty ratio correction circuit 2 is connected between the input terminal 6 and the output terminal 7 for the data signal transfer clock signal. The duty ratio correction circuit 2 includes a first node 31 and a second node 32.

The data signal transfer clock signal is supplied from the input terminal 6 for the data signal transfer clock signal to the first node 31 of the duty ratio correction circuit 2 and the shift register circuit 3 via the buffer amplifier 11. The data signal transfer clock signal supplied from the second node 32 of the duty ratio correction circuit 2 enters the output terminal 7 for the data signal transfer clock signal via the inverter 12.

The data signal is supplied from the input terminal 8 for the data signal to an input terminal of the shift register circuit 3 via the buffer amplifier 13. The data signal received by the shift register circuit 3 is transferred through D flip-flops (hereinafter abbreviated as “D-FFs”) forming the shift register circuit 3 in response to the data signal transfer clock signal, and is supplied from an output terminal of the shift register circuit 3 to the output terminal 9 for the data signal via the buffer amplifier 14. The data signal received by the D-FFs forming the shift register circuit 3 is latched by the latch circuits 4 in response to a latch signal (not shown), and is supplied to the thermal head drive circuit 5.

The thermal head driving IC 1 often has, due to its function, a rectangular IC chip shape with a large IC chip length-to-width ratio. An IC internal wiring line 10 between the input terminal 6 and the output terminal 7 for the data signal transfer clock signal is wired along a long side of the rectangular IC chip. In a case in which the IC internal wiring line 10 for the data signal transfer clock signal is increased in length, the data signal transfer clock signal passing through the IC internal wiring line 10 is distorted in signal waveform due to a resistance and a parasitic capacitance of the IC internal wiring line 10, and a duty ratio of the data signal transfer clock signal is changed. The duty ratio correction circuit 2 corrects the changed duty ratio of the data signal transfer clock signal. The data signal transfer clock signal whose duty ratio has been corrected is supplied from the output terminal 7 for the data signal transfer clock signal.

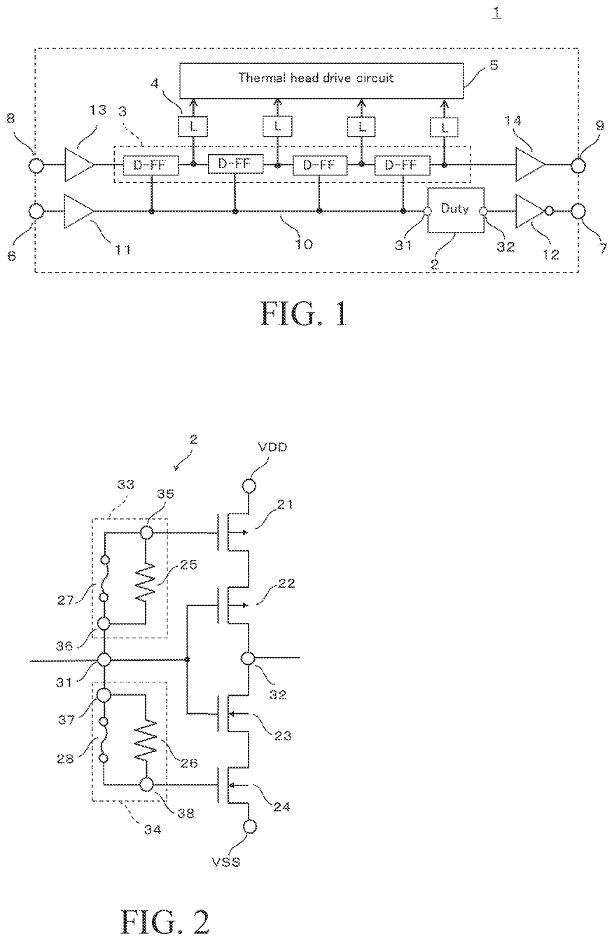

FIG. 2 is a circuit diagram for illustrating an example of the duty ratio correction circuit 2 in the first embodiment. The duty ratio correction circuit 2 includes a first P-channel MOS transistor (hereinafter abbreviated as “PMOS transistor”) 21, a second PMOS transistor 22, a first N-channel MOS transistor (hereinafter abbreviated as “NMOS transistor”) 23, a second NMOS transistor 24, a first resistor circuit 33, a second resistor circuit 34, the first node 31, the second node 32, a VDD terminal, and a VSS terminal. The first resistor circuit 33 includes a first resistor 25, a first fuse 27, a third node 35, and a fourth node 36. The second resistor circuit 34 includes a second resistor 26, a second fuse 28, a fifth node 37, and a sixth node 38.

Connection in the duty ratio correction circuit 2 is described. The first node 31 is connected to a gate terminal of the second PMOS transistor 22, a gate terminal of the first NMOS transistor 23, the fourth node 36 of the first resistor circuit 33, and the fifth node 37 of the second resistor circuit 34. The first PMOS transistor 21 includes a source terminal connected to the VDD terminal, a gate terminal connected to the third node 35 of the first resistor circuit 33, and a drain terminal connected to a source terminal of the second PMOS transistor 22. The second NMOS transistor 24 includes a source terminal connected to the VSS terminal, a gate terminal connected to the sixth node 38, and a drain terminal connected to a source terminal of the first NMOS transistor 23. A drain terminal of the second PMOS transistor 22 and a drain terminal of the first NMOS transistor 23 are connected to the second node 32.

The first resistor 25 and the first fuse 27 of the first resistor circuit 33 are connected in parallel to each other between the third node 35 and the fourth node 36. The second resistor 26 and the second fuse 28 of the second resistor circuit 34 are connected in parallel to each other between the fifth node 37 and the sixth node 38.

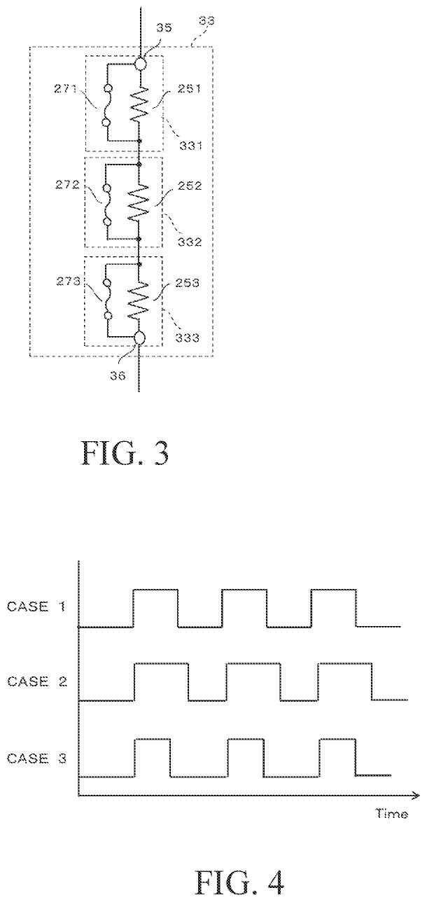

As illustrated in FIG. 3, the first resistor circuit 33 may be configured so that a plurality of resistor circuits are connected in series to each other. Specifically, a resistor 251 and a fuse 271 are connected in parallel to each other so that a resistor circuit 331 is formed. Similarly, a resistor 252 and a fuse 272 are connected in parallel to each other so that a resistor circuit 332 is formed, and a resistor 253 and a fuse 273 are connected in parallel to each other so that a resistor circuit 333 is formed. The first resistor circuit 33 may be configured so that the resistor circuit 331, the resistor circuit 332, and the resistor circuit 333 are connected in series to each other between the third node 35 and the fourth node 36. In the first resistor circuit 33 configured as described above, a resistance value can be adjusted more finely depending on which fuse of the resistor circuit between the third node 35 and the fourth node 36 is cut. Description has been given here of a case in which the number of resistor circuits included in the first resistor circuit 33 is three. However, the number of resistor circuits is not limited to three, and the first resistor circuit 33 may include a larger number of resistor circuits. The second resistor circuit 34 can have a similar configuration.

An operation of the duty ratio correction circuit 2 is described. In the thermal head driving IC 1 of FIG. 1, a clock signal to be supplied to the input terminal 6 for the data signal transfer clock signal has a rectangular wave with a duty ratio of 50% as illustrated in CASE 1 of FIG. 4. FIG. 4 shows the data signal transfer clock signals of from CASE 1 to CASE 3. In FIG. 4, the horizontal axis represents time, and the vertical axis represents voltage of each signal. The wiring line inside of the thermal head driving IC 1 extending from the input terminal 6 to the output terminal 7 for the data signal transfer clock signal is wired along the long side of the rectangular IC. Accordingly, in some cases, the duty ratio of the data signal transfer clock signal is changed from the original ratio of 50% due to the influence of the resistance component and the parasitic capacitance of the wiring line. In some cases, the data signal transfer clock signal is changed so that the duty ratio becomes more than 50% as illustrated in CASE 2 of FIG. 4, and in other cases, the data signal transfer clock is changed so that the duty ratio conversely becomes less than 50% as illustrated in CASE 3 of FIG. 4.

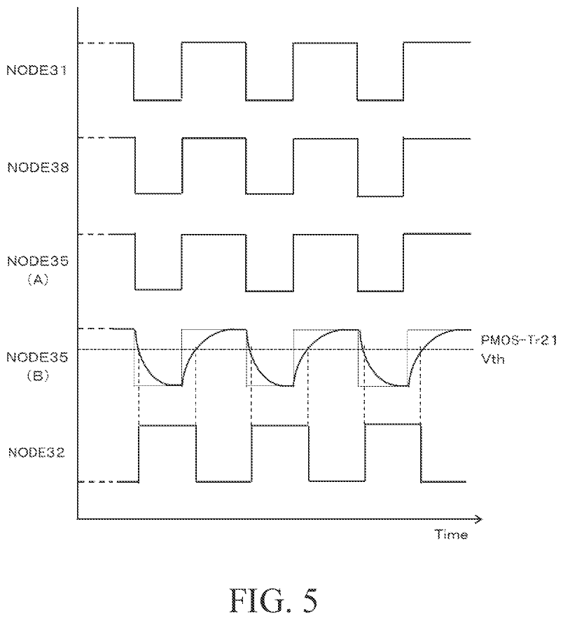

The duty ratio correction in a case in which the duty ratio of the data signal transfer clock signal is changed to more than 50% is described with reference to FIG. 5. FIG. 5 is a diagram for illustrating signals to be handled in the duty ratio correction circuit 2. In FIG. 5, the horizontal axis represents time, and the vertical axis represents voltage of each signal. In a case in which the signal of CASE 2 is supplied to the first node 31 of the duty ratio correction circuit 2, signals indicated by NODE35(A) and NODE38 each being the same as the signal of CASE 2 are transmitted to the third node 35 and the sixth node 38, respectively.

In this case, in a case in which the first fuse 27 of the first resistor circuit 33 is cut, as illustrated in NODE35(B), the signal of the third node 35 achieves a rounder waveform as compared to that of NODE35(A). The signal of the second node 32 of the duty ratio correction circuit 2 becomes a signal inverted at times at which the signal of NODE35(B) crosses a potential of PMOS-Tr21 Vth of FIG. 5. This potential of PMOS-Tr21 Vth is a potential obtained by adding a threshold voltage Vth (for example, −0.7 V) of the first PMOS transistor 21 to a potential of the VDD terminal (potential decreased by 0.7 V). As described above, the data signal transfer clock signal whose duty ratio has become more than 50% can be corrected in duty ratio. Through selection of an appropriate resistance value for the first resistor 25, the data signal transfer clock signal can be corrected to a signal having a duty ratio of 50%.

Further, in a case in which the first resistor circuit 33 is configured so that a plurality of resistor circuits are connected in series to each other as disclosed above, the resistance value of the first resistor circuit 33 can be finely set. The duty ratio correction circuit 2 can finely set the duty ratio correction.

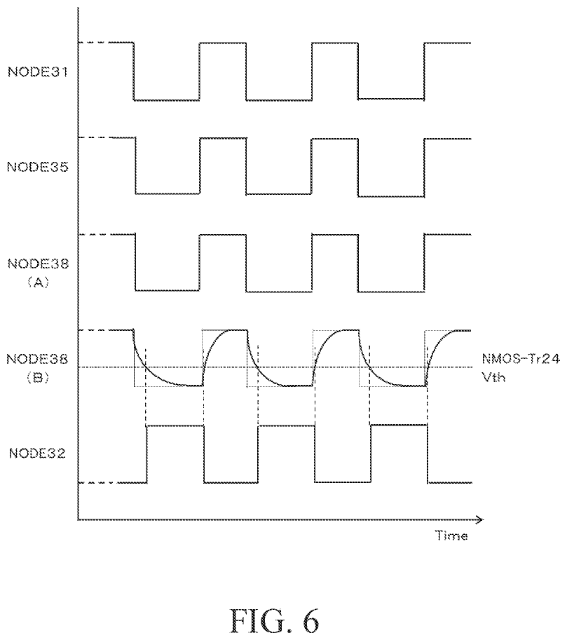

Next, the duty ratio correction in a case in which the duty ratio of the data signal transfer clock signal is changed to less than 50% is described with reference to FIG. 6. FIG. 6 is a diagram for illustrating signals to be handled in the duty ratio correction circuit 2. In FIG. 6, the horizontal axis represents time, and the vertical axis represents voltage of each signal. In a case in which the signal of CASE 3 is supplied to the first node 31 of the duty ratio correction circuit 2, signals indicated by NODE35 and NODE38(A) each being the same as the signal of CASE 2 are transmitted to the third node 35 and the sixth node 38, respectively.

In this case, in a case in which the second fuse 28 of the second resistor circuit 34 is cut, as illustrated in NODE38(B), the signal of the sixth node 38 achieves a rounder waveform as compared to that of NODE38(A). The signal of the second node 32 of the duty ratio correction circuit 2 becomes a signal inverted at times at which the signal of NODE38(B) crosses a potential of NMOS-Tr24 Vth of FIG. 6. This potential of NMOS-Tr24 Vth is a potential obtained by adding a threshold voltage Vth (for example, 0.7 V) of the second NMOS transistor 24 to a potential of the VSS terminal (potential increased by 0.7 V). As described above, the data signal transfer clock signal whose duty ratio has become less than 50% can be corrected in duty ratio. Through selection of an appropriate resistance value for the second resistor 26, the data signal transfer clock signal can be corrected to a signal having a duty ratio of 50%.

Further, similarly to the first resistor circuit, in a case in which the second resistor circuit is configured so that a plurality of resistor circuits are connected in series to each other, the resistance value of the second resistor circuit can be finely set. The duty ratio correction circuit 2 can finely set the duty ratio correction.

As describe above, according to the first embodiment of the present invention, the duty ratio of the clock signal passing through the IC internal wiring line of the thermal head driving IC is maintained while the clock signal is prevented from being distorted.

As a method of cutting the fuse, pattern cut caused by laser light irradiation, cutting caused by heat generation due to current flow, or other methods may be used. Further, the fuse may be replaced with a switch achieved by a non-volatile memory.

The first embodiment has been described assuming that the MOS transistors 21 and 22 are PMOS transistors and the MOS transistors 23 and 24 are NMOS transistors, but the polarities of the VDD terminal and the VSS terminal may be exchanged so that the MOS transistors 21 and 22 may be NMOS transistors and the MOS transistors 23 and 24 may be PMOS transistors. In this case, the PMOS transistor and the NMOS transistor can be distinguished from each other by expressing one transistor as a first-conductivity-type MOS transistor and the other transistor as a second-conductivity-type MOS transistor. Further, the VDD terminal and the VSS terminal can be distinguished from each other by expressing one terminal as a first power supply terminal and the other terminal as a second power supply terminal.

What is claimed is:

1. A thermal head driving integrated circuit, comprising:
an input terminal and an output terminal for a data signal transfer clock signal;
an IC internal wiring line arranged between the input terminal and the output terminal; and
a duty ratio correction circuit connected to the output terminal for the data signal transfer clock signal,
wherein the duty ratio correction circuit includes a first node, a second node, a first first-conductivity-type MOS transistor, a second first-conductivity-type MOS transistor, a first second-conductivity-type MOS transistor, a second second-conductivity-type MOS transistor, a first resistor circuit, a second resistor circuit, a first power supply terminal, and a second power supply terminal, the first resistor circuit including a first resistor and a first fuse connected in parallel to each other between a third node and a fourth node, the second resistor circuit including a second resistor and a second fuse connected in parallel to each other between a fifth node and a sixth node,
wherein the first first-conductivity-type MOS transistor includes a source terminal connected to the first power supply terminal, a gate terminal connected to the third node, and a drain terminal connected to a source terminal of the second first-conductivity-type MOS transistor,
wherein the second first-conductivity-type MOS transistor includes a gate terminal connected to the first node and the fourth node, and a drain terminal connected to the second node,
wherein the first second-conductivity-type MOS transistor includes a gate terminal connected to the first node and the fifth node, a drain terminal connected to the second node, and a source terminal connected to a drain terminal of the second second-conductivity-type MOS transistor, and
wherein the second second-conductivity-type MOS transistor includes a gate terminal connected to the sixth node, and a source terminal connected to the second power supply terminal.

2. The thermal head driving integrated circuit according to claim 1,
wherein the first resistor circuit further includes, between the third node and the fourth node, one or more resistor circuits each including a resistor and a fuse connected in parallel to each other, and
wherein the second resistor circuit further includes, between the fifth node and the sixth node, one or more resistor circuits each including a resistor and a fuse connected in parallel to each other.

3. A method of manufacturing the thermal head driving integrated circuit of claim 1,
the thermal head driving integrated circuit including: an input terminal and an output terminal for a data signal transfer clock signal; an IC internal wiring line arranged between the input terminal and the output terminal;
and a duty ratio correction circuit connected to the output terminal for the data signal transfer clock signal,
the duty ratio correction circuit including a first node, a second node, a first first-conductivity-type MOS transistor, a second first-conductivity-type MOS transistor, a first second-conductivity-type MOS transistor, a second second-conductivity-type MOS transistor, a first resistor circuit, a second resistor circuit, a first power supply terminal, and a second power supply terminal, the first resistor circuit including a first resistor and a first fuse connected in parallel to each other between a third node and a fourth node, the second resistor circuit including a second resistor and a second fuse connected in parallel to each other between a fifth node and a sixth node,
the first first-conductivity-type MOS transistor including a source terminal connected to the first power supply terminal, a gate terminal connected to the third node, and a drain terminal connected to a source terminal of the second first-conductivity-type MOS transistor,
the second first-conductivity-type MOS transistor including a gate terminal connected to the first node and the fourth node, and a drain terminal connected to the second node,
the first second-conductivity-type MOS transistor including a gate terminal connected to the first node and the fifth node, a drain terminal connected to the second node, and a source terminal connected to a drain terminal of the second second-conductivity-type MOS transistor,
the second second-conductivity-type MOS transistor including a gate terminal connected to the sixth node, and a source terminal connected to the second power supply terminal,
the method comprising cutting a fuse of one of the first resistor circuit or the second resistor circuit.

4. The method of manufacturing the thermal head driving integrated circuit according to claim 3,
wherein the first resistor circuit further includes, between the third node and the fourth node, one or more resistor circuits each including a resistor and a fuse connected in parallel to each other, and
wherein the second resistor circuit further includes, between the fifth node and the sixth node, one or more resistor circuits each including a resistor and a fuse connected in parallel to each other.
